(19) United States
(12) Patent Application Publication
(10) Pub. No.: US 2018/0190477 A1
(43) Pub. Date: Jul. 5, 2018

(54) MAGNETRON PLATE, MAGNETRON APPARATUS AND MAGNETRON SPUTTERING DEVICE

(71) Applicant: BOE TECHNOLOGY GROUP CO., LTD., Beijing (CN)

(72) Inventors: Zhongyuan SUN, Beijing (CN); Xiaohu LI, Beijing (CN)

(73) Assignee: BOE TECHNOLOGY GROUP CO., LTD., Beijing (CN)

(21) Appl. No.: 15/507,484

(22) PCT Filed: Feb. 23, 2016
(86) PCT No.: PCT/CN2016/074364

§ 371 Date: Feb. 28, 2017

(30) Foreign Application Priority Data
Sep. 2, 2015 (CN) 201510556068.2

(51) Int. Cl. H01J 37/34; C23C 14/35

(52) U.S. Cl. CPC H01J 37/3452; H01L 51/56; C23C 14/35; H01J 37/3405

(57) ABSTRACT

The present disclosure provides a magnetron plate and a magnetron apparatus. The magnetron plate is configured to generate a magnetic field during a magnetron sputtering process. The magnetron plate includes a plurality of detachable magnetron plate units for generating the magnetic field. Like poles of all magnets of the magnetron plate units are arranged on a same side of the magnetron plate. The magnetron apparatus is configured to control a film-forming position during a magnetron sputtering process, and includes the above-described magnetron plate.

### CROSS-REFERENCE TO RELATED APPLICATION

This application claims a priority to Chinese Patent Application No. 201510556068.2 filed on Sep. 2, 2015, the disclosure of which is incorporated in its entirety by reference herein.

### TECHNICAL FIELD

The present disclosure relates to the field of liquid crystal display (LCD) technology, in particular to a magnetron plate, a magnetron apparatus and a magnetron sputtering device.

### BACKGROUND

Organic light-emitting diodes (OLEDs) are expected to be the next-generation display devices due to its flexibility. Compared with traditional LCD panels, OLED panel has a series of advantages such as having a fast response speed, a higher contrast ratio, a wide viewing angle, a low temperature resistance, and enabling flexibility. OLED top emission devices usually use transparent cathodes. As the transparent cathode, a thin metal such as Mg, Ag or the like, or a transparent oxide such as indium-doped zinc oxide (IZO), may be used. In general, the preparation of IZO thin film requires the use of magnetron sputtering process.

Magnetron plates are conventional members of magnetron sputtering equipments, and used to greatly increase the probability by which the charged particles impact the target under the force of magnetic field. Since OLED devices are susceptible to water and oxygen, wet-related processes cannot be performed thereon, which requires the OLED magnetron sputtering equipments to be provided with a mask plate for patterning. A mask plate component in the related art as shown in FIG. 1, includes a mask plate frame 101 and a mask plate net 102 fixed to the mask plate frame 101. The mask plate net 102 is fabricated in accordance with a drawing of a display screen, so there is a mask plate hollow 103 at a position corresponding to the display screen. The mask plate is often used in conjunction with a magnetron apparatus having a magnetron plate, and the magnetron apparatus can direct a position of film formation of the target material by directing the direction in which the plasma impacts the target. Because the magnetic field of the magnetron plate can guide the plasma to impact the target, the deposition of the IZO thin film will occur in the range of movement of the magnetron plate (including the mask plate frame and the mask plate net). However, at present, both the mask plate frame and the mask plate net are made of a metal material, the deposited IZO film will fall off due to the stress when the IZO film gets too thick, resulting in a large number of particle contamination. Therefore, the mask plate of the OLED magnetron sputtering equipment needs to be replaced regularly.

For the existing magnetron plate, after the IZO film has deposited on the mask plate, it is difficult to clean up the IZO film by a process such as an etching process, so the mask plates with a certain amount of IZO film deposited thereon usually are directly shipped back to the manufacturers for scrap disposal, resulting in a lot of waste.

### SUMMARY

In view of the above, the present disclosure provides a magnetron plate, a magnetron apparatus and a magnetron sputtering device, so as to reduce the scrap rate of mask plate during the magnetron sputtering process.

In an aspect, the present disclosure provides a magnetron plate for generating a magnetic field during a magnetron sputtering process. The magnetron plate includes a plurality of detachable magnetron plate units configured to generate the magnetic field.

Optionally, the magnetron plate includes a magnetron plate unit fixation mechanism, wherein the plurality of magnetron plate units is detachably secured to the magnetron plate unit fixation mechanism in a corresponding manner.

Optionally, the magnetron plate unit fixation mechanism includes a base plate provided with a plurality of grooves, and the plurality of magnetron plate units is detachably secured to the plurality of the grooves respectively.

Optionally, the plurality of grooves is arranged in a matrix form.

Optionally, the magnetron plate fixation mechanism includes a base plate provided with a plurality of adsorption mechanisms, and the plurality of magnetron plate units is detachably secured to the plurality of the adsorption mechanisms respectively.

Optionally, each of the plurality of the magnetron plate units includes at least one magnet.

Optionally, the at least one magnet is of a rectangular shape.

Optionally, all magnets of the magnetron plate units are arranged on a same side of the magnetron plate at sides of the magnets that are of a same polarity.

In another aspect, the present disclosure further provides a magnetron apparatus for controlling a film-forming position during a magnetron sputtering process, including the magnetron plate provided by the embodiments of the present disclosure.

Optionally, the magnetron apparatus further includes a moving mechanism connected to the magnetron plate and configured to control movement of the magnetron plate.

Optionally, the moving mechanism includes a first movement control mechanism and a second movement control mechanism, the first movement control mechanism is configured to control the magnetron plate to move in a first direction, and the second movement control mechanism is configured to move the magnetron plate in a second direction different from the first direction.

Optionally, the first movement control mechanism includes: a first screw rod arranged in a first direction; and a first electric motor configured to drive the first screw rod, the first screw rod and the magnetron plate are connected in a manner that the first screw rod and the magnetron plate may move relative to each other, and thereby when the first electric motor drives the first screw rod, the magnetron plate moves in the first direction.

Optionally, the second movement control mechanism includes: a second screw rod arranged in the second direction; and a second electric motor configured to drive the second screw rod, the second screw rod and the magnetron plate are connected in a manner that the second screw rod and the magnetron plate may move relative to each other, and thereby when the second electric motor drives the second screw rod, the magnetron plate moves in the second direction.

Optionally, the first direction is perpendicular to the second direction.

Optionally, the first direction is in parallel with a first side of the magnetron plate, and the second direction is in parallel with a second side of the magnetron plate, wherein the first side of the magnetron plate and the second side of the magnetron plate are adjacent sides.

In still another aspect, the present disclosure further provides a magnetron sputtering device including the magnetron apparatus provided by the embodiments of the present disclosure.

From above it can be seen that according to the magnetron apparatus of the present disclosure, a plurality of magnetron plate units of a small size is used to replace the magnetron plate of a large size of the related art, and during the magnetron sputtering process, at least one magnetron plate unit is assembled to form a pattern corresponding to the magnetron region, and therefore, there is no need to generate the magnetic field of a maximum size all the time in the magnetron sputtering process. As a result, the probability that a target material sputters on the mask plate frame is reduced, and at the same time, the probability that the target material sputters on the edge of the mask frame net is also reduced to a certain extent. Thus, even if after a long time of use and many batches of substrates are made, only a small amount of target material is deposited on the mask plate frame or the mask frame net, which reduces the cost of replacing the mask plate frame and mask frame net.

### BRIEF DESCRIPTION OF THE DRAWINGS

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art may obtain the other drawings without any creative effort.

FIG. 1 is a schematic diagram showing components of a mask plate in the related art;

FIG. 2A is a schematic diagram showing a magnetron plate according to some embodiments of the present disclosure;

FIG. 2B is a schematic diagram showing a magnetron apparatus according to some embodiments of the present disclosure;

FIG. 3 is a schematic diagram showing a assemble of a magnetron plate unit according to some embodiments of the present disclosure; and

FIG. 4 is a schematic diagram showing a magnetron plate unit according to some embodiments of the present disclosure.

### DETAILED DESCRIPTION

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “a” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

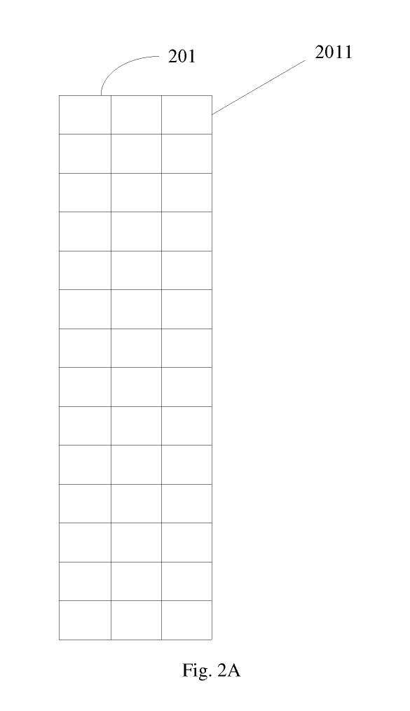

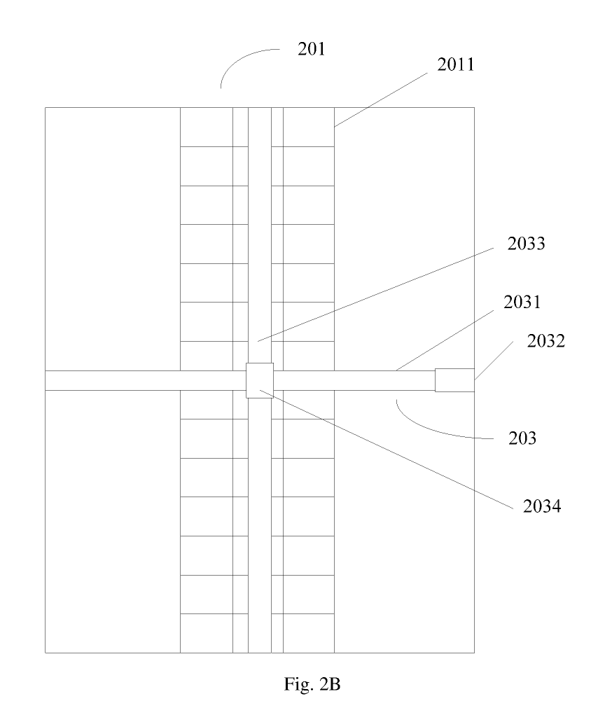

The present disclosure provides in some embodiments a magnetron plate for generating a magnetic field during a magnetron sputtering process. As shown in FIG. 2A, the magnetron plate 201 includes a plurality of detachable magnetron plate unit 2011 configured to generate the magnetic field.

According to the magnetron plate of the present disclosure, it is able to assemble a pattern corresponding to the film-forming target region by the plurality of magnetron plate units, so as to enable the magnetron range to correspond to the film-forming target region. When the film-forming target region is small, the magnetron range can be reduced; and when the film-forming target region is large, the magnetron range can be enlarged. Since the film-forming target region is changeable and not fixed, only a small amount of target material is deposited on the mask plate frame or mask frame net after a long time of use, therefore the service life of the magnetron plate is increased.

In some embodiments of the present disclosure, the magnetron plate includes a magnetron plate unit fixation mechanism. The magnetron plate units are detachably secured to the magnetron plate unit fixation mechanism.

The magnetron plate unit fixation mechanism is made of a non-magnetic, non-conductive hard material.

In some embodiments of the present disclosure, the magnetron plate unit fixation mechanism includes a base plate provided with a plurality of grooves and the magnetron plate units are detachably secured to the grooves.

In some embodiments of the present disclosure, the magnetron plate unit includes at least one magnet. To be specific, one magnetron plate unit can be one separate magnet.

In some embodiments of the present disclosure, the magnet may be of a rectangular shape, which may enable the magnetic field to be distributed evenly and facilitate the uniformity of the sputtering region. In addition, in the case that the magnets of the plurality of magnetron plate units are arranged on the magnetron plate, like poles of all magnets of the magnetron plate units are arranged on a same side of the magnetron plate. In this way, the generated electric field is better and facilitates the uniformity of sputtering.

In some embodiments of the present disclosure, the plurality of grooves is arranged in a matrix form.

In some embodiments of the present disclosure, the magnetron plate fixation mechanism includes a base plate provided with a plurality of adsorption mechanisms and the magnetron plate units are detachably secured to the adsorption mechanisms.

The present disclosure further provides a magnetron apparatus for controlling a film-forming position during a magnetron sputtering process, which includes any of the magnetron plate provided by the present disclosure. FIG. 2B is a schematic diagram showing the magnetron apparatus.

From above it can be seen that, according to the magnetron apparatus of the present disclosure, the magnetron plate includes the plurality of detachable magnetron plate units. During the magnetron sputtering process, the magnetron range may be changed by assembling or disassembling magnetron plate units. Therefore, a shape or a size of the magnetron range may correspond to a shape or a size of a film-forming target substrate or another target product. Therefore, when the region where the film is to be formed is small, the magnetron range can be reduced, so as to reduce the probability that the film is deposited on the mask plate frame and the probability that the film is deposited on an region around the mask plate net during the magnetron sputtering process. As a result, the process of scrapping the mask plate due to excessive deposition of the film material on the mask plate net or mask plate frame may be slowed down, and thereby the scrap rate of the mask plate may be reduced.

In some embodiments of the present disclosure, the magnetron apparatus further includes a moving mechanism, which is connected to the magnetron plate and configured to control the movement of the magnetron plate. The moving mechanism enables the magnetron plate to move in a more flexible manner, so that the sputtering range and sputtering positions are more flexibly controllable. Therefore, it is able to achieve a large sputtering range with only a few magnetron plate units by flexibly moving the magnetron plate units.

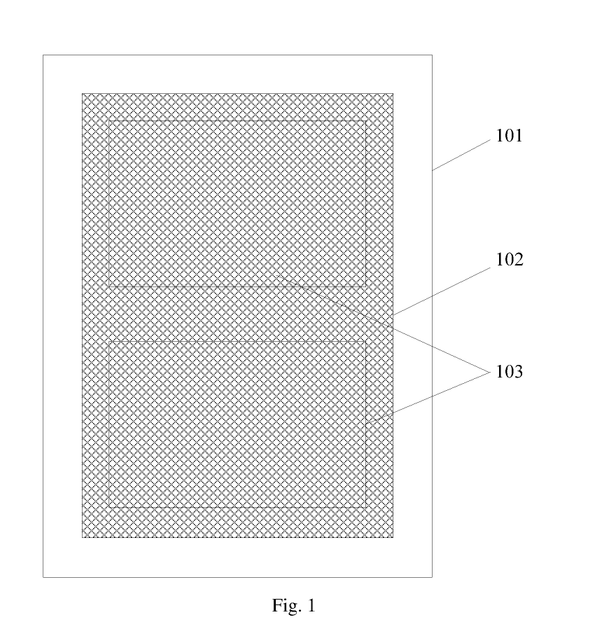

In some embodiments of the present disclosure, the magnetron plate is used in conjunction with the mask plate. A plurality of magnetron plate units is provided on the magnetron plate at a position corresponding to the hollow regions of the mask plate frame. When the film-forming region is small, a small number of the magnetron plate units are used to form a pattern corresponding to the film-forming region, and a magnetron region corresponding to the small film-forming region is formed; When the film-forming region is large, a large number of the magnetron plate unit are used to form a pattern corresponding to the large film-forming region, and a magnetron region corresponding to the large film-forming region is formed. To be specific, the mask plate component structure may refer to FIG. 1.

The magnetron plate unit is a device that may generate magnetic field and has a same function as the magnetron plate, and the range of the magnetic field generated by the magnetron plate unit is less than that generated by the magnetron plate in the related art. To be specific, the magnetron plate unit may be a magnet of a small size.

With respect to a certain type of the magnetron sputtering equipment, for example, the total price of the mask plate component is about ten thousand Chinese Yuan, of which the mask plate frame is of a price of several thousand Chinese Yuan. Based on the current experience, when a thickness of the film deposited on the mask plate reaches tens of thousands of angstroms, it is necessary to replace the mask plate with a new one. In order to manufacture the normal substrates, the mask plate will need to be replaced with a new one after only a few batches of the substrates are made.

In the present disclosure, with the design of the magnetron plate unit whose position is changeable, the magnetic field range is controlled within the range of the opening region of the mask plate, so as to reduce the target material deposited on the mask plate frame. Even if there is inevitably contamination of target material particles on the mask plate net, the deposition probability that the target material is deposited on the mask plate frame can be reduced to a great extent, so that the mask plate frame can be reused while only the mask plate net needs to be replaced with a new one periodically. Therefore, at least about 50% of the cost for purchasing the mask plate can be saved. In addition, in the related art, a position of the magnetron plate relative to the mask plate is fixed, but in the present disclosure, the magnetron plate units of the magnetron plate can be flexibly arranged at positions according to the hollow position of the mask plate, so that the needs of different patterns of the mask plates may be met, thereby widening the application range thereof, and saving the cost.

In some embodiments of the present disclosure, the magnetron plate further includes a magnetron plate unit fixation mechanism. The magnetron plate unit fixation mechanism may be a base plate provided with a plurality of grooves. The magnetron plate units are detachably secured to the grooves. The plurality of grooves is arranged in a matrix form.

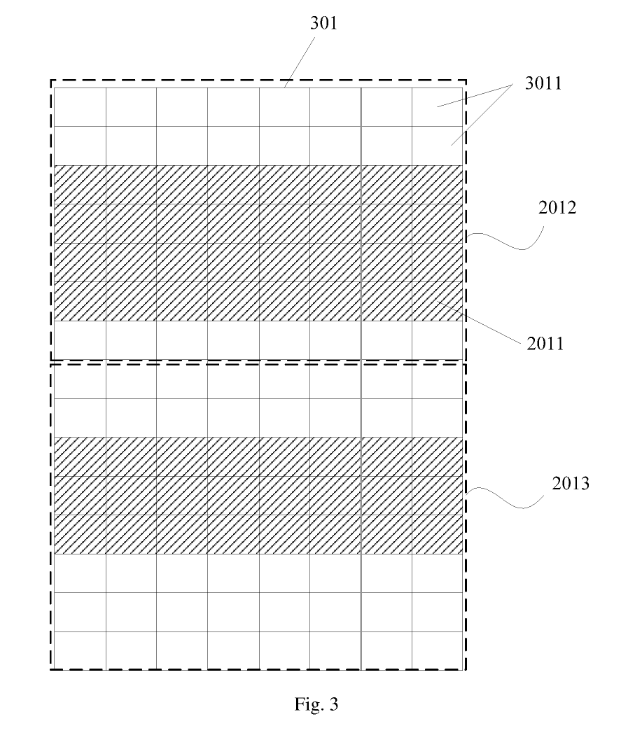

Through the base plate and the grooves of the base plate, it is able to allow the magnetron plate units to be more firmly assembled together with each other and easily disassembled. In addition, it is further allow the existence of two film-forming region on one target substrate or another target products during the magnetron sputtering process. As shown in FIG. 3, when the base plate 301 is used to facilitate disassembling and assembling the magnetron plate units 2011, the plurality of magnetron plate units 2011 may be assembled into two magnetron regions 2012 and 2013 (i.e., the two regions indicated by the dashed lines in FIG. 3), which may be used for the target substrate or another target product with two film-forming regions. The base plate 301 is provided with a plurality of grooves 3011, a size of each of the grooves 3001 is identical to that of the magnetron plate unit 2011. In order to distinguish the groove 3011 and the magnetron plate unit 2011, the grooves with the magnetron plate unit 2011 arranged therein in FIG. 3 is indicated by shadows.

In some other embodiments of the present disclosure, the magnetron plate units may be assembled or disassembled in other manners. For example, a plurality of clamping mechanism may be provided at a peripheral region of the magnetron plate unit. In other words, a slot may be provided at an edge of one of the magnetron plate units and a projection matched to the slot may be provided at an edge of another one of the magnetron plate units. The projection is capable for being firmly clamped in the slot, so that every two magnetron plate units can be assembled and disassembled through the clamping mechanism. For another example, the two magnetron plate units may be connected to each other by mechanical fasteners such as screws. Further, the magnetron plate units may be secured to the magnetron plate unit fixation mechanism by the above-described clamping mechanism, the mechanical fastener or the like.

In some other embodiments of the present disclosure, the base plate may be provided with adsorption mechanisms, which is configured to absorb the magnetron plate unit, so as to assemble and disassemble the magnetron plate units. In some embodiments of the present disclosure, as shown in FIG. 2B, the magnetron apparatus further includes a moving mechanism 203, which is connected to the magnetron plate 201 and configured to control movement of the magnetron plate 201.

In the case that the magnetron plate unit is clamped and assembled with the assistance of the base plate, the moving mechanism 203 may be directly connected to the base plate and is configured to move the magnetron plate unit 2011 by moving the base plate.

During the magnetron sputtering process, it is required to use ions to bombard the target material. In order to improve the efficiency of bombarding the target material by the ions, the magnetron plate is provided on a back side of the target material away from the ion source. In use of the magnetron apparatus provided in the present disclosure, both the magnetron plate and the moving mechanism are arranged on the back side of the target material, so as to control a direction of ion bombardment.

In some embodiments of the present disclosure, the moving mechanism is configured to move the magnetron plate unit in a plane where the magnetron plate is located, so as to enable the magnetron plate unit to move to any position within the range of the magnetron plate. To be specific, the moving mechanism includes a first movement control mechanism and a second movement control mechanism. The first movement control mechanism is configured to control the magnetron plate to move in a horizontal direction, and the second movement control mechanism is configured to control the magnetron plate to move in a vertical direction. In this way, the magnetron plate may be moved in two directions under the control of the moving mechanism, therefore it is able to achieve a large sputtering region with only a few magnetron plate units, thereby saving the cost and achieving a more flexible application.

In some embodiments of the present disclosure, referring to FIG. 2B, the first movement control mechanism includes a first screw rod 2031 arranged in a horizontal direction and a first electric motor 2032 configured to drive the first screw rod 2031 to move the magnetron plate 201 in a horizontal direction.

With the first screw rod 2031 and the first electric motor 2032, it is able to move the magnetron plate 201 in a horizontal direction. As a result, during the magnetron sputtering process, when a length of the film-forming region in a horizontal direction is longer than that of the magnetron plate 201 in the horizontal direction, it is able to move the magnetron plate 201 by the moving mechanism 203. Therefore it is able to control the magnetron sputtering in a large film-forming region by using a magnetron plate of a small size.

In some embodiments of the present disclosure, referring to FIG. 2B, the second movement control mechanism includes a second screw rod 2033 arranged in a vertical direction and a second electric motor 2034 configured to drive the second screw rod 2033. The second screw rod 2033 is connected to the magnetron plate 201, and the second screw rod 2033 and the magnetron plate 201 may move relative to each other, so as to enable the magnetron plate 201 to move in a vertical direction when the second electric motor 2034 drives the second screw rod 2033.

It should be noted that, the first movement control mechanism and the second movement control mechanism may be other control mechanisms, as long as they can control the magnetron plate to move in both the horizontal and vertical directions.

When the screw rods are used, one of the first screw rod and the second screw rod is fixed while the other screw rod is movable respect to the one screw rod, which may be implemented as one of follows.

In some embodiments, the first screw rod 2031 may be fixed and the magnetron plate 201 is moveable in a horizontal direction with respect to the first screw rod 2031. At the same time, the second screw rod 2033 is moveable in a horizontal direction and a vertical direction with respect to the first screw rod 2031. The position of the second screw rod 2033 relative to the position of the magnetron plate 201 is fixed. When the position is to be adjusted, the first electric motor 2032 is driven to move the magnetron plate 201 and the second screw rod 2033 in a horizontal direction with respect to the first screw rod 2031, and then the second electric motor 2034 is driven to move the second screw rod 2033 in a vertical direction with respect to the first screw rod 2031, thereby to move the magnetron plate 201 in the vertical direction with respect to the first screw rod 2031 since the position of the second screw rod 2033 relative to the position of the magnetron plate 201 is fixed.

In some other embodiments, the first screw rod 2031 is fixed, and the magnetron plate 201 is arranged on the second screw rod in a moveable manner, and the second electric motor may drive the magnetron plate to move in an extending direction of the second screw rod, i.e., a vertical direction, and the magnetron plate may move in a horizontal direction with respect to the first screw rod 2031 with the assistance of the second screw rod. The second screw rod 2033 may move in a horizontal direction with respect to the first screw rod 2031, and the second screw rod 2033 is fixed relative to the first screw rod 2031 in a vertical direction. When the position is to be adjusted, the first electric motor 2032 is driven to move the magnetron plate 201 and the second screw rod 2033 simultaneously in a horizontal direction with respect to the first screw rod 2031, and then the second electric motor 2034 is driven to move the magnetron plate 201 in a vertical direction, thereby the magnetron plate 201 moves respect to the first screw rod 2031 and the second screw rod 2033.

In some other embodiments, the second screw rod 2033 is fixed and the magnetron plate 201 is moveable in a vertical direction with respect to the second screw rod 2033. The first screw rod 2031 is moveable in a vertical direction and a horizontal direction with respect to the second screw rod 2033. The position of the first screw rod 2031 relative to the position of the magnetron plate 201 is fixed. When the position is to be adjusted, the second electric motor 2034 is driven to move the magnetron plate 201 and the first screw rod 2031 in a vertical direction with respect to the second screw rod 2033, and then the first electric motor 2032 is driven to move the first screw rod 2031 in a horizontal direction with respect to the second screw rod 2033, thereby to move the magnetron plate 201 in a horizontal direction with respect to the second screw rod 2033 since the position of the first screw rod 2031 relative to the position of the magnetron plate 201 is fixed.

In some other embodiments, the second screw rod 2033 is fixed and the magnetron plate 201 is arranged on the first screw rod in a moveable manner, and the first electric motor may drive the magnetron plate to move in an extending direction of the first screw rod, i.e., a horizontal direction. The first screw rod 2031 is moveable in a vertical direction with respect to second screw rod 2033, with the assistance of the second screw rod. Since the magnetron plate is arranged on the first screw rod, the magnetron plate may also be moveable in a vertical direction with respect to second screw rod 2033 with the assistance of the first screw rod. The first screw rod 2031 and the second screw rod 2033 are relatively fixed in the horizontal direction. When the position is to be adjusted, the second electric motor 2034 is driven at first, so as to move the magnetron plate 201 and the first screw rod 2031 simultaneously in a vertical direction with respect to the second screw rod 2033; then, the first electric motor 2032 is driven to move the magnetron plate 201 in a horizontal direction, thereby the magnetron plate 201 moves with respect to the second screw rod 2033 and the first screw rod 2032.

The orders of driving the first electric motor 2032 and the second electric motor 2034 in the above embodiment are changeable.

According to the magnetron apparatus of the embodiments of the present disclosure, the magnetron plate includes a plurality of magnetron plate units. The total length of the plurality of magnetron plate units in the horizontal direction or the vertical direction may be less than that of the film-forming region of the target product in the horizontal direction or the vertical direction. Therefore, the moving mechanisms may be arranged in the vertical direction as well as in the horizontal direction, so that the positions of the magnetron plate units may be adjusted within the whole plane where the magnetron plate is located. As a result, the positions of the magnetron plate units can be adjusted according to the specific size and shape of the film-forming region of the target product so as to achieve the formation of the film in the film-forming region.

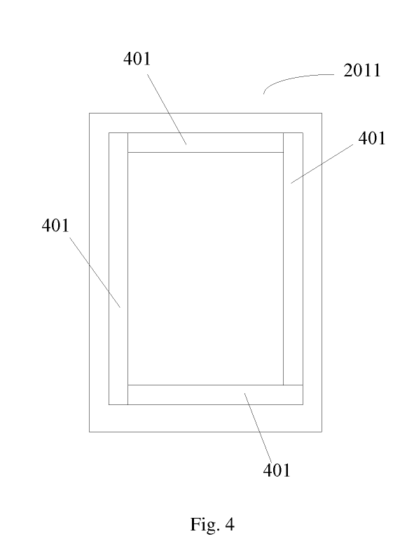

In some embodiments of the present disclosure, the magnetron plate unit is of a rectangular shape. To be specific, the magnetron plate unit may be one piece of magnet of the rectangular shape or composed of a plurality of magnets. As shown in FIG. 4, the magnetron plate unit 2011 includes a plurality of strip-shaped magnets 401, which form a rectangular frame

In order to enable the magnetron plate units to form a pattern with a shape corresponding to the film-forming region which may have different shapes, the magnetron plate unit may be of various plane geometric shape.

When the magnetron apparatus provided by the present disclosure is to be used, the number and the position of the magnetron plate units of the magnetron plate may be adjusted according to the size and shape of the film-forming target, so that the number and the position of the magnetron plate units match the size and shape of the film-forming target.

To be specific, when the magnetron apparatus provided by the present disclosure is used, the position of the magnetron plate may be adjusted according to the position of the film-forming target, so that the position of the magnetic field generated by the magnetron plate may matches the position of the film-forming target.

The position of the magnetron plate may be adjusted prior to the magnetron sputtering process, so that the magnetron plate units may be moved to a position corresponding to the film-forming region. Alternatively, the position of the magnetron plate may be adjusted during the magnetron sputtering process, so that a magnetic field can be generated within a wide range with a small number of the magnetron plate units in the case where the film-forming region is irregular in shape. The position adjustment may be carried out in only one direction or in two or more directions.

In a specific embodiment of the present disclosure, the moving mechanism includes a moving mechanism in the horizontal direction for moving the magnetron plate units in the horizontal direction in a plane where the magnetron plate is located, and a moving mechanism in the vertical direction for moving the magnetron plate units in the vertical direction in the plane where the magnetron plate is located. When the magnetron apparatus is in use, the position of the magnetron plate unit can be adjusted in the horizontal direction in the plane where the magnetron plate is located according to the position of the film-forming target so that the position of magnetron plate unit in the horizontal direction in the plane where the magnetron plate is located corresponds to the film-forming region; and similarly, the position of the magnetron plate unit can be adjusted in the vertical direction in the plane where the magnetron plate is located according to the position of the film-forming target, so that the position of magnetron plate unit in the vertical direction in the plane where the magnetron plate is located corresponds to the film-forming region.

From above it can be seen that, according to the magnetron apparatus of the present disclosure, a plurality of magnetron plate units of a small size is used to replace the magnetron plate of a large size of the related art, and during the magnetron sputtering process, at least one magnetron plate unit is assembled to form a pattern corresponding to the magnetron region, and therefore, there is no need to generate the magnetic field of a maximum size all the time in the magnetron sputtering process. As a result, the probability that a target material sputters on the mask plate frame is reduced, and at the same time, the probability that the target material sputters on the edge of the mask frame net is also reduced to a certain extent. Thus, even if after a long time of use and many batches of substrates are made, only a small amount of target material is deposited on the mask plate frame or the mask frame net, which reduces the cost of replacing the mask plate frame and mask frame net.

It should be understood that the various embodiments described herein are for the purpose of illustration and explanation only and are not intended to limit the present disclosure. And the features in the embodiments as well as embodiments of the present disclosure may be combined with each other if no conflict occurs.

A person skilled in the art may make further modifications and improvements without departing from the principle and spirit of the present disclosure, and these modifications and improvements shall also fall within the scope of the present disclosure.

1. A magnetron plate for generating a magnetic field during a magnetron sputtering process, wherein the magnetron plate comprises a plurality of detachable magnetron plate units configured to generate the magnetic field.

2. The magnetron plate according to claim 1, further comprising a magnetron plate unit fixation mechanism, wherein the plurality of magnetron plate units is detachably secured to the magnetron plate unit fixation mechanism.

3. The magnetron plate according to claim 2, wherein the magnetron plate unit fixation mechanism comprises a base plate provided with a plurality of grooves, and the plurality of magnetron plate units is detachably secured to the plurality of the grooves respectively.

4. The magnetron plate according to claim 3, wherein the plurality of grooves is arranged in a matrix form.

5. The magnetron plate according to claim 2, wherein the magnetron plate fixation mechanism comprises a base plate provided with a plurality of adsorption mechanisms, and the plurality of magnetron plate units is detachably secured to the plurality of the adsorption mechanisms respectively.

6. The magnetron plate according to claim 1, wherein each of the plurality of the magnetron plate units comprises at least one magnet.

7. The magnetron plate according to claim 6, wherein the at least one magnet is of a rectangular shape.

8. The magnetron plate according to claim 6, wherein like poles of all magnets of the magnetron plate units are arranged on a same side of the magnetron plate.

9. A magnetron apparatus for controlling a film-forming position during a magnetron sputtering process, comprising the magnetron plate according to claim 1.

10. The magnetron apparatus according to claim 9, further comprising a moving mechanism connected to the magnetron plate and configured to control movement of the magnetron plate.

11. The magnetron apparatus according to claim 10, wherein
the moving mechanism comprises a first movement control mechanism and a second movement control mechanism,
the first movement control mechanism is configured to move the magnetron plate in a first direction, and
the second movement control mechanism is configured to move the magnetron plate in a second direction different from the first direction.

12. The magnetron apparatus according to claim 11, wherein the first movement control mechanism comprises:
a first screw rod arranged in a first direction; and
a first electric motor configured to drive the first screw rod and thereby move the magnetron plate in the first direction.

13. The magnetron apparatus according to claim 11, wherein the second movement control mechanism comprises:
a second screw rod arranged in the second direction; and
a second electric motor configured to drive the second screw rod and thereby move the magnetron plate in the second direction.

14. The magnetron apparatus according to claim 11, wherein the first direction is perpendicular to the second direction.

15. The magnetron apparatus according to claim 11, wherein
the first direction is in parallel with a first side of the magnetron plate, and
the second direction is in parallel with a second side of the magnetron plate,
wherein the first side of the magnetron plate and the second side of the magnetron plate are adjacent sides.

16. A magnetron sputtering device comprising the magnetron apparatus according to claim 9.

17. The magnetron apparatus according to claim 16, further comprising a moving mechanism connected to the magnetron plate and configured to control movement of the magnetron plate.

18. The magnetron apparatus according to claim 17, wherein
the moving mechanism comprises a first movement control mechanism and a second movement control mechanism,
the first movement control mechanism is configured to move the magnetron plate in a first direction, and
the second movement control mechanism is configured to move the magnetron plate in a second direction different from the first direction.

19. The magnetron apparatus according to claim 18, wherein the first movement control mechanism comprises:
a first screw rod arranged in a first direction; and
a first electric motor configured to drive the first screw rod and thereby move the magnetron plate in the first direction.

20. The magnetron apparatus according to claim 18, wherein the second movement control mechanism comprises:
a second screw rod arranged in the second direction; and
a second electric motor configured to drive the second screw rod and thereby move the magnetron plate in the second direction.
